(19) United States
(12) Patent Application Publication
(10) Pub. No.: US 2024/0410929 A1
(43) Pub. Date: Dec. 12, 2024

(54) FAULT DETECTION AND LOCALIZATION

(71) Applicant: Alliance for Sustainable Energy, LLC, Golden, CO (US)

(72) Inventors: Ahmed Samir Abdelaal ZAMZAM, Highlands Ranch, CO (US); Jing WANG, Littleton, CO (US); Soham CHAKRABORTY, Golden, CO (US); Yue CHEN, Charlotte, NC (US)

(21) Appl. No.: 18/674,654

(22) Filed: May 24, 2024

Related U.S. Application Data
(60) Provisional application No. 63/504,140, filed on May 24, 2023.
(60) Provisional application No. 63/516,161, filed on Jul. 28, 2023.
(60) Provisional application No. 63/613,057, filed on Dec. 20, 2023.
(60) Provisional application No. 63/613,063, filed on Dec. 21, 2023.

(51) Int. Cl. G01R 31/08; H02H 1/00; H02H 7/26

(52) U.S. Cl. CPC G01R 31/088; G01R 31/086; H02H 7/26; H02H 1/0092

(57) ABSTRACT

An example device includes at least one processor configured to determine, based on a value of a voltage and a value of a current at a location of an electrical power system, a plurality of voltage features and a plurality of current features corresponding to the location. The at least one processor may be further configured to determine, based on the plurality of voltage features and the plurality of current features, using a classification model, whether a fault has occurred in the electrical power system and responsive to determining that a fault has occurred, causing a protective device in the electrical power system to trip.

### CROSS-REFERENCE TO RELATED APPLICATIONS

This application claims the benefit of: U.S. Provisional Application No. 63/504,140, titled “HIERARCHICAL DATA-DRIVEN FAULT PROTECTION” and filed May 24, 2023, U.S. Provisional Application No. 63/516,161, titled “HIERARCHICAL DATA-DRIVEN FAULT PROTECTION” and filed Jul. 28, 2023, U.S. Provisional Application No. 63/613,057, titled “LEARNING-BASED FAULT DETECTION AND TRIGGER-BASED FAULT TIME ESTIMATION” and filed Dec. 20, 2023, and U.S. Provisional Application No. 63/613,063, titled “LOCAL SYNCHRONIZATION OF DISTRIBUTED MACHINE LEARNING-BASED RELAY DECISIONS” and filed Dec. 21, 2023, the entire content of each of which is incorporated herein by reference.

### GOVERNMENT LICENSE RIGHTS

This invention was made with government support under Contract No. DE-AC36-08GO28308 awarded by the Department of Energy. The government has certain rights in the invention.

### BACKGROUND

In a power system, promptly localizing and isolating faults is crucial for maintaining system reliability and safety. Existing protection schemes achieve this by using relay devices, which are configured with pre-defined thresholds for parameters such as voltage and current. As distributed energy resources, including inverter-based resources, become more prevalent in today's power systems, system characteristics result in reduced appropriateness of such pre-defined thresholds.

### SUMMARY

In one example, A device includes at least one processor configured to determine, based on a value of a voltage and a value of a current at a location of an electrical power system, a plurality of voltage features and a plurality of current features corresponding to the location. The at least one processor may be further configured to determine, based on the plurality of voltage features and the plurality of current features, using a classification model, whether a fault has occurred in the electrical power system and, responsive to determining that a fault has occurred, causing a protective device in the electrical power system to trip.

In another example, a device includes at least one processor configured to determine, based on a value of a voltage and a value of a current at a first location of an electrical power system, using a classification model, a respective indication, corresponding to the first location, of whether a fault is upstream or downstream from the first location. The at least one processor may be further configured to determine, based on the respective indication corresponding to the first location and a respective indication corresponding to a neighboring location, whether the fault is in a neighborhood of the first location and, responsive to determining that the fault is in a neighborhood of the first location, causing a protective device in the electrical power system that is in the neighborhood to trip.

In another example, a device includes at least one processor configured to determine, based on a value of a voltage and a value of a current at a first location of an electrical power system, using a classification model, a respective indication, corresponding to the first location, of whether a fault is upstream or downstream from the first location. The at least one processor may be further configured to determine, based on the respective indication corresponding to the first location and a respective indication corresponding to a neighboring location, the neighboring location being within a decision zone that includes the first location whether the fault is the decision zone and responsive to determining that the fault is in the decision zone, causing a protective device in the electrical power system that is in the decision zone to trip.

The details of one or more examples are set forth in the accompanying drawings and the description below. Other features, objects, and advantages will be apparent from the description and drawings, and from the claims.

### BRIEF DESCRIPTION OF DRAWINGS

FIG. 1 is a conceptual diagram illustrating an example electrical power system having protective relays configured to perform fault detection, in accordance with one or more aspects of the present disclosure.

FIG. 2 is a set of graphical plots illustrating the change in features determined based on measurements at relay 104A of FIG. 1 for a fault at location F101 of FIG. 1, of type ABCG with impedance of 1.4Ω at t=0.5 s.

FIG. 3 is a set of graphical plots illustrating the change in features determined based on measurements at relay 104L of FIG. 1 for a fault at location F110 of FIG. 1, of type AG with impedance of 10.1Ω at t=0.5 s.

FIG. 4 is a flow diagram illustrating example operations for performing fault detection, in accordance with one or more aspects of the present disclosure.

FIG. 5 is a flow diagram illustrating example operations for performing fault time estimation, in accordance with one or more aspects of the present disclosure.

FIG. 6 is a conceptual diagram illustrating an example electrical power system having protective relays configured to perform hierarchical fault localization in accordance with one or more aspects of the present disclosure.

FIG. 7 is a flow diagram illustrating example operations for performing hierarchical fault localization, in accordance with one or more aspects of the present disclosure.

FIG. 8 is a conceptual diagram illustrating an example electrical power system (system 802) having protective relays configured to perform distributed fault localization in accordance with one or more aspects of the present disclosure.

FIG. 9 is a conceptual diagram illustrating communication among relays 604 of FIG. 8 when performing the distributed fault localization techniques described with respect to FIG. 8.

FIG. 10 is a flow diagram illustrating example operations for performing distributed fault localization in accordance with one or more aspects of the present disclosure.

### DETAILED DESCRIPTION

In one aspect, the present disclosure provides techniques for fault detection and fault time estimation in an electrical power system. For example, a protective relay in an electrical power system or other device having a processor may be configured with a classifier (also referred to herein as a classification model) that allows the device to determine whether a fault has occurred in the system based on real-time (or near real-time) voltage and current measurements. The protective relay or other device may additionally or alternatively be configured to estimate the time of the fault based on real-time (or near real-time) active and reactive power measurements.

In another aspect, the present disclosure provides techniques for decentralized fault localization. For example, a protective relay in an electrical power system or other device having a processor may be configured with a classifier (also referred to herein as a classification model) that allows the device to determine whether a fault is upstream or downstream from the protective relay or other device based on real-time (or near real-time) voltage and current measurements. In some examples, the protective relay or other device may make such binary determinations of fault direction based on measurements at its own location. In some examples, the protective relay or other device may communicate with neighboring devices to make such binary determinations of fault direction based additionally at measurements at other devices' locations.

The protective relay or other device may utilize its binary determination and that of neighboring devices to determine the location of the fault. In some examples, such fault localization may be performed in a hierarchical fashion, with the protective relay or other device utilizing its binary determination of fault direction along with determinations from neighboring devices in a decision zone that includes the protective relay or other device, to determine whether the fault is in the decision zone and, e.g., trip a circuit breaker if the fault is determined to be in the decision zone. If the fault is determined to not be in the decision zone, the protective relay or other device may notify neighboring devices in another decision zone.

In some examples, the protective relay or other device may determine the location of a fault in a distributed fashion, utilizing its binary determination of fault direction along with determinations from its neighboring devices to determine whether the fault is in a neighborhood of the protective relay or other device and, e.g., trip a circuit breaker if the fault is determined to be in the neighborhood.

In another aspect, the present disclosure provides techniques for coordination of communication among neighbor devices during fault localization. For example, a protective relay or other device may employ a “hold and wait” strategy to ensure communications with neighboring devices are timely and not missed by those meant to receive them.

In various examples, the techniques of the present disclosure are described herein as being performed by or implemented in a particular device or system, such as a protective relay. In some examples, however, the techniques of the present disclosure may additionally or alternatively be performed by or implemented in other devices or systems. For instance, the techniques of the present disclosure are generally described herein as being performed by a protective relay. In some examples, however, such techniques may be performed by various other devices or combinations of devices having the ability to perform such techniques. Examples of other devices or combinations of devices may include digital fault recorders, phasor measurement units, smart switches, sectionalizers, and fault location, isolation, and service restoration (FLISR) services or other components of a distribution management system. In addition, some of the techniques of the present disclosure are described herein as being utilized and/or useful in a microgrid setting. In various examples, however, the techniques of the present disclosure may be utilized in various electrical power systems, including those with levels of penetration of distributed energy resources varying from none to complete.

Design of reliable protection systems for microgrids and similar electrical power systems has been a complex and pivotal issue for researchers both in industry and academia. The presence of distributed energy resources (DERs) introduces unique and dynamic behaviors in the event of a fault, distinguishing such systems from conventional power distribution systems. Challenges include the bidirectional flow of the fault current in the network, a reduction in the fault current level due to DERs, and changes in the fault current level and flow direction depending on the mode of operation of the power system, such as grid-tied and islanded configurations of a microgrid.

Several related-art protection schemes have been proposed, including communication-assisted differential protection, adaptive directional overcurrent protection, sequence superimposed current-based overcurrent protection, admittance relay-based protection, and hybrid tripping characteristics-based protection. These protection schemes provide a certain degree of reliability in protecting a microgrid with mixed DERs, including rotating machine-based DERs, such as diesel generation sets, gas turbine resources, and inverter-based resource (IBR) DERs, such as photovoltaic (PV) grid-following (GFL) IBRs and battery energy storage system (BESS) grid-forming (GFM) IBRs. In the emerging 100% renewable power systems, however, additional challenges include: limited fault current contributions by the IBRs, which are restricted by the switches and the fault-limiters; fluctuating fault current levels based on IBR's operational status due to the variability of the renewable resources; and a lack of established fault models of IBRs, which can vary depending on the selection of the control schemes and the fault-limiting logic under balanced/unbalanced faults.

These challenges underscore the need for innovative fault detection solutions, particularly in the context of 100% renewable power systems, to ensure the reliability and effectiveness of the protection systems. With the advent of artificial intelligence techniques, the focus has shifted to using machine learning (ML) algorithms for developing more robust protection systems. Decision tree (DT)-based algorithms for relays have been proposed using wavelet-based and differential quantity-based features. Classical DT-based methods, however, suffer from high variance and over-fitting issues. Multi-layer, feed-forward, artificial neural network-based algorithms have been developed based on instantaneous voltage and current measurements at relay points for fault classification and location identification. However, over-complexities due to a large number of neurons in the hidden layers and the impacts of limited, sparce, and noisy data affect the outcome.

Other related-art approaches include extreme ML and random forest algorithms, which use features extracted via Hilbert-Huang transformations and principal component analysis from measured voltage and current data. A threshold-based protection scheme based on Kalman filter residuals and the total harmonic distortion (THD) of measured current by the relays has been proposed. Support vector machine (SVM)-based classifiers have also been used to detect and localize faults in a microgrid based on unique features extracted from discrete wavelet transformation and discrete Fourier transformation of the prefault and postfault voltage and current measurements. However, existing SVM-based fault detection methods rely on classifiers (Kernels) that are mostly nonlinear and are trained on post-computed features that are extremely difficult to implement in real low-cost, microcontroller-based numerical relays. Furthermore, despite successful fault detection in microgrids with mixed DERs, most existing SVM classifier-based protection schemes are unable to detect faults under the intermittent behavior of renewable DERs.

In contrast to the related-art techniques mentioned above, the fault detection techniques of the present disclosure provide a comprehensive and efficient approach to generating training data sets capturing the intermittency of renewable DERs, thereby allowing for the training of SVM classifiers that maintain reliability under varying levels of low-fault current situations within a 100% renewable microgrid. Furthermore, the techniques of the present disclosure utilize classical features, such as positive- and negative-sequence components and the THD of the voltage and current waveforms measured by the relays, which facilitates implementation on microcontroller-based relays. In addition, the techniques provided herein streamline integration into relay logic by developing a linear SVM classifier to detect faults.

Yet further, the techniques of the present disclosure provide differential power-based fault time estimation, which can, in some examples, be triggered by the SVM-based fault detection techniques described herein. These additional techniques ensure synchronicity among multiple relays in a microgrid, which is helpful in any data-driven fault localization scheme.

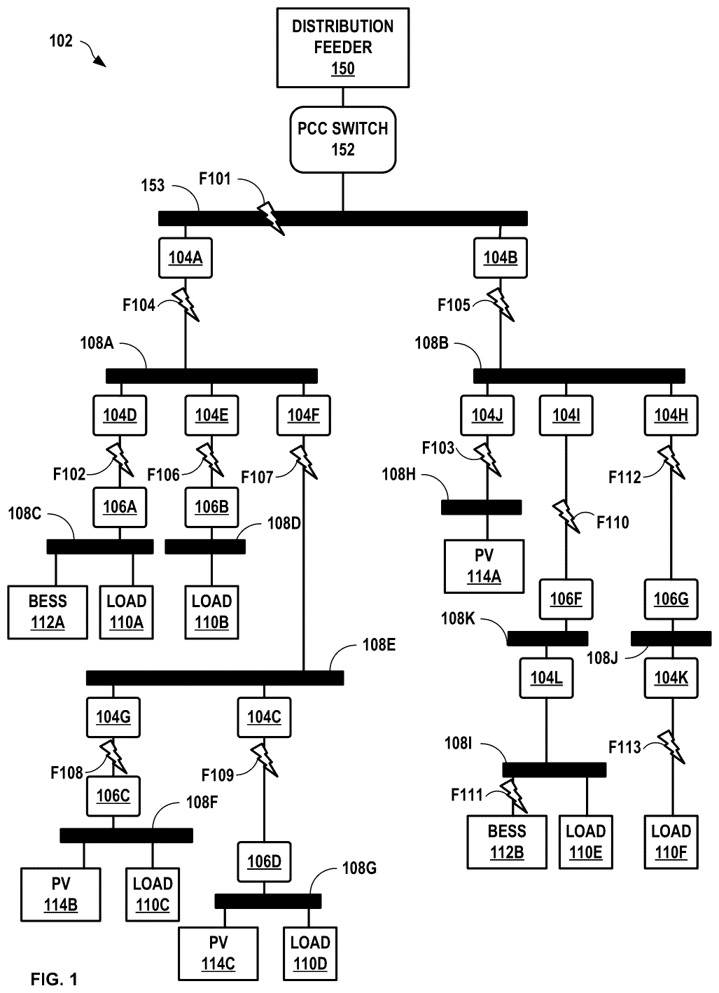

FIG. 1 is a conceptual diagram illustrating an example electrical power system (system 102) having protective relays configured to perform fault detection, in accordance with one or more aspects of the present disclosure. System 102 is generally based on Feeder 2 of the Banshee distribution network benchmark system, which is a benchmarking microgrid system used to evaluate microgrid controllers, protection, and cybersecurity. As shown in the example of FIG. 1, system 102 includes distribution feeder 150, point of common coupling switch 152 (“PCC switch 152”), feeder bus 153, relays 104A-104L (collectively “relays 104”), transformers 106A-106G (collectively “transformers 106”), busses 108A-108K (collectively “busses 108”), and loads 110A-110F (collectively “loads 110”). System 102 also includes battery energy storage system 112A (“BESS 112A”), rated at 2.5 MVA, and photovoltaic inverter-based resource 114A (“PV 114A”), rated at 2 MW, connected to Bus 108C and Bus 108H, respectively. System 102 further includes BESS 112B, with a rating of 1 MVA, at Bus 108I, PV 114B, with a rating of 0.5 MW, at Bus 108F, and PV 114C, with a rating of 1 MW, at Bus 108G. System 102 of FIG. 1 represents only one example of a system having devices configured to perform the fault detection and/or fault time estimation techniques described herein, and various other systems, having additional components, fewer components, and/or other components, may be used in accordance with the present disclosure.

In the example of FIG. 1, BESS 112A and 112B (collectively “BESSs 112”) operate with GFM control, including power tracking for grid-connected mode and voltage-frequency (VF) power sharing control for islanded mode. PV 114A, 114B, and 114C (“PVs 114”) operate in GFL control while following three modes: (i) fixed power factor; (ii) P-Q dispatch; and (iii) volt-volt ampere reactive control. BESSs 112 and PVs 114 respond to abnormal voltages and possess voltage ride-through capabilities compliant with IEEE 1547-20188 Category III. Relays 104 may represent protective relays and are configured to perform the fault detection and fault time estimation techniques provided herein, as further described below. Distribution feeder 150, PCC switch 152, feeder bus 153, busses 108, loads 110, and transformers 106 may be considered standard components. Further details regarding ratings and other information about such standard components are beyond the scope of this disclosure and can be found in the literature.

In accordance with the fault detection techniques of the present disclosure, training datasets may be generated for a target electrical power system by performing simulations of the system. These simulations may encompass a wide range of fault conditions, including different impedances, fault types, and fault locations. For example, system 102 of FIG. 1 may be simulated a total of S times, covering both prefault and postfault situations and including simulations in which faults occurred at the 13 locations denoted in FIG. 1 as F101-F113.

The simulations may also account for variations in load demand (e.g., demand of loads 110), solar irradiance of the PV IBRs (e.g., irradiance of PVs 114), and different operational modes of IBRs (e.g., operational modes of BESSs 112 and PVs 114), including both grid-tied and islanded configurations. In various examples, the scenarios may include various fault locations, fault types, fault impedances under varying loading conditions, varying renewable generations, and various IBR control modes.

It is well established that different types of faults in an electrical power system, such as a microgrid, will generate different types of signatures in the waveform of the voltage and current measured by relays in the system. In accordance with the fault detection techniques provided herein, the following prominent features may be utilized to generate training datasets for the target system: a magnitude of the positive sequence (V₊ᵥₑ), the negative sequence (V₋ᵥₑ), and the zero sequence (V₀) of the voltage waveform, vₐ(t), v_{b}(t), v_{c}(t), measured at relays in the target system; a magnitude of the positive sequence (I₊ᵥₑ), the negative sequence (I₋ᵥₑ), and the zero sequence (I₀) of the current waveform, iₐ(t), i_{b}(t), i_{c}(t), measured at relays in the target system; the total harmonic distortion (THD) in each phase of the voltage waveforms—i.e., V_{THD}^{a}, V_{THD}^{b}, and V_{THD}^{c}, at relays in the target system; and the THD in each phase of the current waveforms—i.e., I_{THD}^{a}, I_{THD}^{b}, and I_{THD}^{c}, at relays in the target system. The twelve features provided above may be extracted from the instantaneous voltage and current waveform for all the tested scenarios. In some examples, features may be extracted once each power cycle. In some examples, features may be extracted at some other interval, such as multiple times per power cycle, every other power cycle, every 5 power cycles, every 0.01 s, every 0.005 s, every 0.02 s, or at another interval.

As a specific example, for each of the S scenarios simulated on system 102 of FIG. 1, the instantaneous per-phase voltage and current may be obtained at relays throughout system 102 (e.g., relays 104) in each power cycle. From these values, the twelve features may be extracted as follows.

The magnitudes of positive, negative, and zero sequence components of the voltage may be determined as:

$${V}_{+ v e} = \vert {\overline{V}}_{+ v e} \vert := [ {\overline{V}}_{a} + α {\overline{V}}_{b} + {α}^{2} {\overline{V}}_{c} ] / 3 ,$$

$${V}_{- v e} = \vert {\overline{V}}_{- v e} \vert := [ {\overline{V}}_{a} + {α}^{2} {\overline{V}}_{b} + α {\overline{V}}_{c} ] / 3 , and$$

$${V}_{0} = \vert {\overline{V}}_{0} \vert := [ {\overline{V}}_{a} + {\overline{V}}_{b} + {\overline{V}}_{c} ] / 3 ,$$

where V̅ₐ, V̅_{b}, and V̅_{c} are the phasor quantities corresponding to vₐ(t), v_{b}(t), and v_{c}(t), respectively. Here, α: =1∠120°.

The magnitudes of positive, negative, and zero sequence components of the current may be determined as:

$${I}_{+ v e} = \vert {\overline{I}}_{+ v e} \vert := [ {\overline{I}}_{a} + α {\overline{I}}_{b} + {α}^{2} {\overline{I}}_{c} ] / 3 ,$$

$${I}_{- v e} = \vert {\overline{I}}_{- v e} \vert := [ {\overline{I}}_{a} + {α}^{2} {\overline{I}}_{b} + α {\overline{I}}_{c} ] / 3 , and$$

$${I}_{0} = \vert {\overline{I}}_{0} \vert := [ {\overline{I}}_{a} + {\overline{I}}_{b} + {\overline{I}}_{c} ] / 3 ,$$

where Īₐ, Ī_{b}, and Ī_{c} are the phasor quantities corresponding to iₐ(t), i_{b}(t), and i_{c}(t), respectively.

The THD of phase y of the voltage waveform may be determined as:

$${V}_{THD}^{y} := \sqrt{[ {\sum }_{h > 1} {\vert {\overline{V}}_{y , h} \vert}^{2} ] / [ {\vert {\overline{V}}_{y , 1} \vert}^{2} + {\sum }_{h > 1} {\vert {\overline{V}}_{y , h} \vert}^{2} ]} ,$$

where |V̅_{y,h}| is the magnitude of the h^{th} harmonic component of v_{y}(t). As a result, Hᵥ_{ₐ}, Hᵥ_{_{b}}, and Hᵥ_{_{c}} are the THD of the voltages in phase a, b, and c, respectively.

The THD of phase y of the current waveform may be determined as:

$${I}_{THD}^{y} := \sqrt{[ {\sum }_{h > 1} {\vert {\overline{I}}_{y , h} \vert}^{2} ] / [ {\vert {\overline{I}}_{y , 1} \vert}^{2} + {\sum }_{h > 1} {\vert {\overline{I}}_{y , h} \vert}^{2} ]} ,$$

where |I_{y,h}| is the magnitude of the h^{th} harmonic component of i_{y}(t). As a result, Hᵢ_{ₐ}, Hᵢ_{_{b}}, and Hᵢ_{_{c}} are the THD of the currents in phase a, b, and c, respectively.

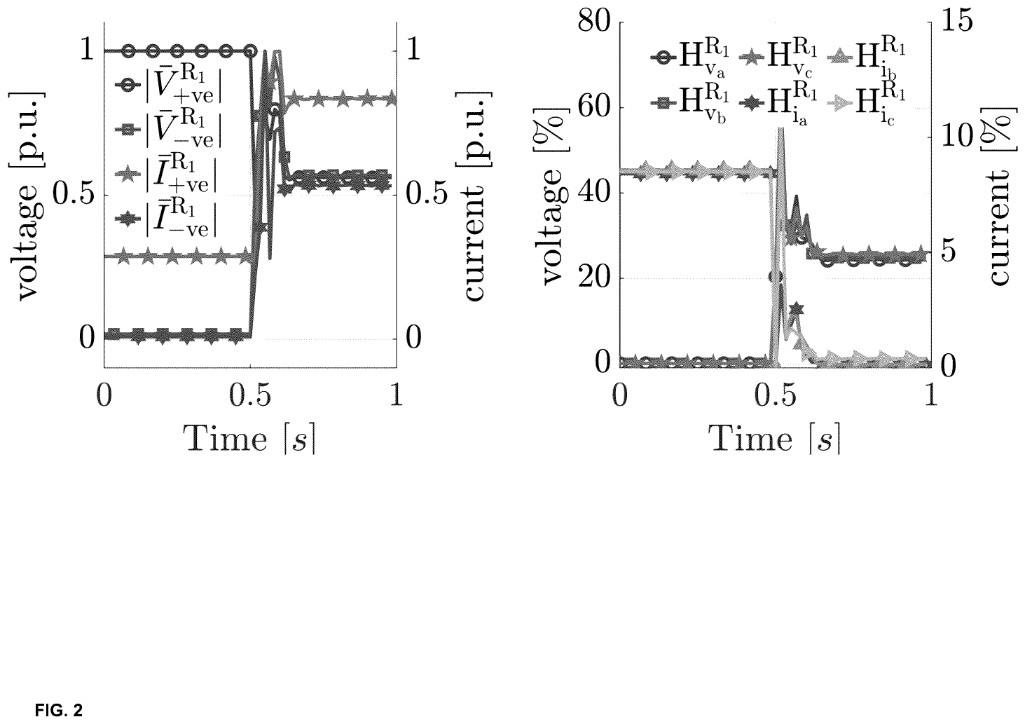

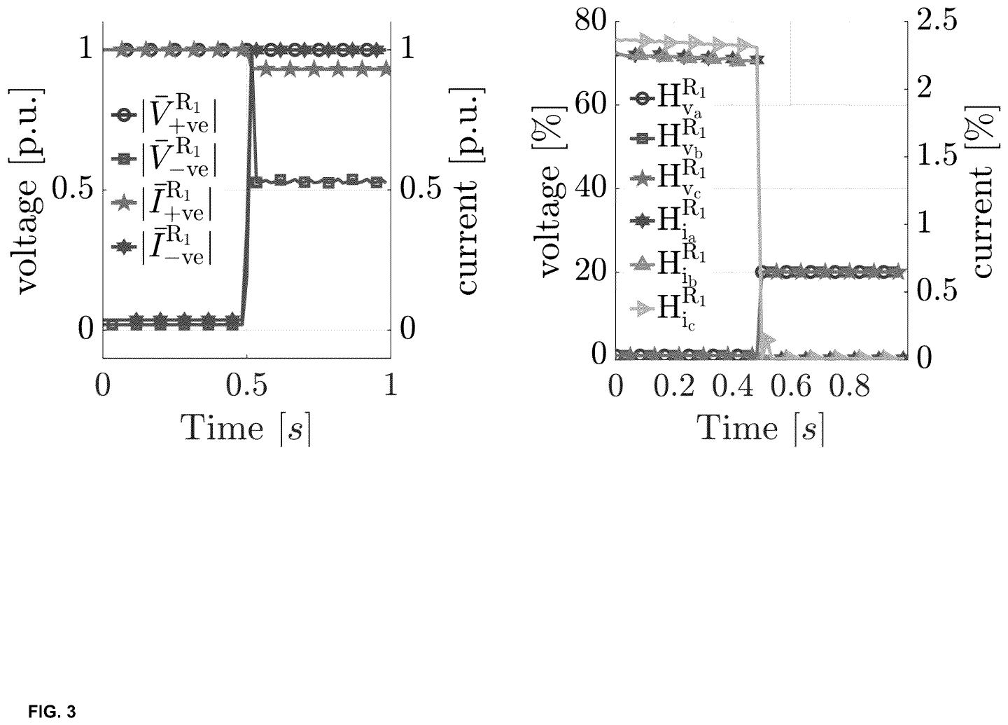

FIG. 2 is a set of graphical plots illustrating the change in features determined based on measurements at relay 104A for a fault at location F101, of type ABCG with impedance of 1.4Ω at t=0.5 s. FIG. 3 is a set of graphical plots illustrating the change in features determined based on measurements at relay 104L for a fault at location F110, of type AG with impedance of 10.1Ω at t=0.5 s. As can be seen in FIGS. 2 and 3, there is a significant amount of change in the features before and after the fault inception. These observations justify the selection of these features for the classifier.

In accordance with the fault detection techniques of the present disclosure, a respective classifier (or classification model) may be trained for use by a relay in the target electrical power system. For instance, the techniques described herein may use a support vector machine (SVM)-based classification algorithm to classify the S number of data sets, X:=[X₁, X₂, X₃, . . . , X_{S}], into two different classes, labeled as {1, −1} with 1 representing a determination that a fault has not occurred and −1 representing a determination that a fault has occurred.

Here, the complete set of features is:

$${X}_{s} = {[ {V}_{+ ve} , {V}_{- ve} , {V}_{0} , {I}_{+ ve} , {I}_{- ve} , {I}_{0} , {V}_{THD}^{a} , {V}_{THD}^{b} , {V}_{THD}^{c} , {I}_{THD}^{a} , {I}_{THD}^{b} , {I}_{THD}^{c} ]}^{T} .$$

In each simulation, for the k^{th} relay, there are nₚᵣₑ number of Xₛ^{k} and nₚₒₛₜ number of Xₛ^{k}, determined prefault and postfault, respectively. Hence, there is a total of N=S×nₚᵣₑ+S×nₚₒₛₜ number of Xₛ^{k} for the k^{th} relay.

The output target is selected such that tₙ=−1 and tₙ=1 if Xₛ^{k}[n] belong to the prefault and postfault conditions, respectively. Based on the optimization method of the SVM-based classifier, the goal is to fine the optimized linear classifier (e.g., a hyperplane of order 10) for the k^{th} relay. That is, the classification problem seeks to find a hyperplane that can optimally separate the S data into these two different classes by finding a linear hyperplane class that can be formulated as y(Xₙ)=W^{T}Xₙ+b. The goal of this off-line training is to find, for relays in the target system, a suitable vector W and a coefficient b that results in good accuracy, precision, and recall. This off-line training process is performed for each relay measured in S to generate a respective classifier for such relay.

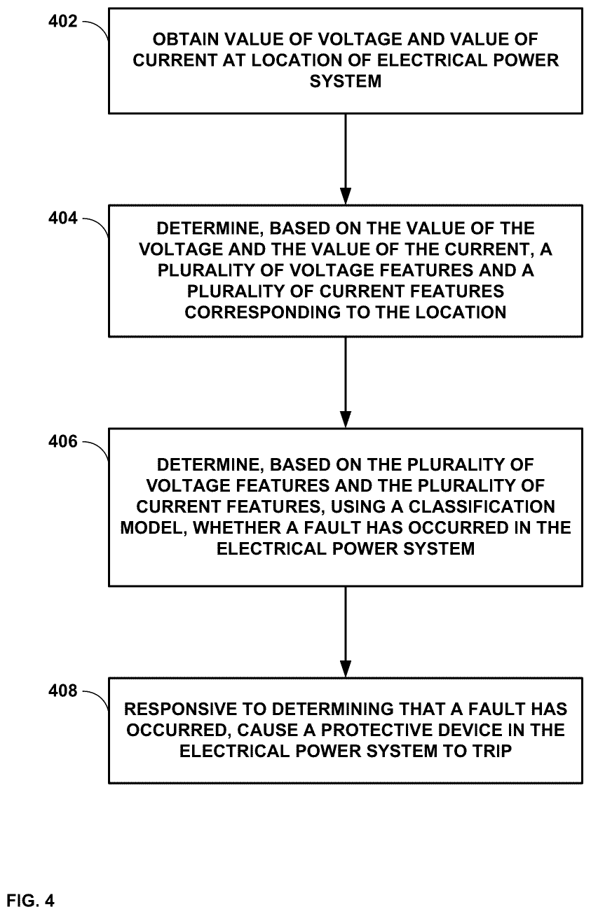

FIG. 4 is a flow diagram illustrating example operations for performing fault detection, in accordance with one or more aspects of the present disclosure. FIG. 4 represents only one example process for performing fault detection as described herein, and various other or additional operations may be used in other examples. The example operations of FIG. 4 are described below within the context of FIG. 1.

In the example of FIG. 4, a computing device having at least one processor may be configured to measure, receive, or otherwise obtain a value of a voltage and a value of a current at a location of an electrical power system (402). For example, relay 104A of system 102 may be configured to measure the instantaneous voltage and current at relay 104A. Typical protective relays may measure the instantaneous voltage and current at a relatively high frequency, such as 1024 measurements per power cycle. In some examples, the computing device may retain voltage and current values for a time period, such as for one minute, for one second, for 10 power cycles, or for some other period.

In the example of FIG. 4, the computing device may be further configured to determine, based on the value of the voltage and the value of the current, a plurality of voltage features and a plurality of current features corresponding to the location (404). For example, relay 104A may be configured to determine the twelve features detailed above, which correspond to the location of relay 104A.

In the example of FIG. 4, the computing device may be further configured to determine, based on the plurality of voltage features and the plurality of current features, using a classification model, whether a fault has occurred in the electrical power system (406). In some examples, the classification model may be an SVM-based classification model (or classifier). For example, relay 104A may utilize a classification model, generated as detailed above with respect to FIGS. 1-3, that receives features of the voltage and current as experienced by relay 104A. Such features may be represented as a vector of features. The classification model may receive the vector of features in real-time (or near real-time) and output a binary determination-either that a fault has occurred or that a fault has not occurred.

In the example of FIG. 4, the computing device may be further configured to cause, responsive to determining that a fault has occurred, a protective device in the electrical power system to trip or otherwise operate (408). For example, responsive to relay 104A determining that a fault has occurred, relay 104A may trip a circuit breaker of relay 104A.

In some examples, causing a protective device in the electrical power system to trip may entail, responsive to determining that a fault has occurred, performing additional or alternative operations that lead to a protective device tripping. For instance, the computing device may be additionally configured to perform one or more of the other techniques disclosed herein, including fault time estimation and/or fault localization. In some examples, the computing device may be configured, responsive to determining that a fault has occurred, to not perform any further operations. That is, in some examples a computing device may be configured to perform operations 402, 404, and 406, but not perform operation 408.

In some examples, the operations of FIG. 4 may be performed in an iterative fashion. That is, while only a single flow of operations is shown, operations 402, 404, 406, and/or 408 may be performed any number of times. In some examples, the operations may be performed periodically, such as every power cycle of the electrical power system, or at some other interval. For instance, a computing device may perform operations 402, 404, and 406 every power cycle, and may not perform operation 408 unless a fault is determined. Additionally, in some examples, operations 402, 404, 406, and/or 408 may be iteratively performed at different frequencies.

The classifier detailed herein detects the inception of a fault using the steady-state phasor quantities, which may cause a subcycle-to-cycle period-level delay in detection from the true fault inception time. Thus, for the same fault inception time, different relays might detect the fault at different times. This delay in fault detection may lead to nuisance operation of a relay if/when coordinating with neighboring relays. To avoid such potential issues, the techniques of the present disclosure also include fault time estimation, allowing devices to estimate the fault inception as close as possible to the real fault time. These techniques may utilize some instantaneous quantity, such as rate of change of active power dp(t)/dt, and rate of change of reactive power, dq(t)/dt, at the device. Both the active and reactive power stay fairly constant before the fault under a specific loading and generation in the electrical power system. Therefore, the trajectory of dp(t)/dt and dq(t)/dt will be fairly linear and the values will be close to zero. However, both quantities will drastically change their trajectory from the fault time. By observing the trajectories and checking the time instant when any of these two trajectories crosses a preassigned upper and lower threshold limit, the fault time test can be estimated as close as possible to the true fault time tr. For a particular relay, the instantaneous active power and reactive power in power units (p.u.) may be formulated as follows:

p(t):=[vₐ(t)iₐ(t)+v_{b}(t)i_{b}(t)+v_{c}(t)i_{c}(t)]/L_{rated}, and

q(t):=1/\sqrt{3}[{v_{b}(t)−v_{c}(t)}iₐ(t)+{v_{c}(t)−vₐ(t)}i_{b}(t)+{vₐ(t)−v_{c}(t)}i_{c}(t)]/L_{rated},

where L_{rated} is the kVA rating of the line where the relay is employed.

In the ideal case, the threshold limit would be zero. That is, theoretically, the fault time would be whenever the rate of change of active power or the rate of change of reactive power changes at all. In reality, devices in the network all involve a certain amount of error in measurement and thus a threshold of zero would likely lead to inaccurate fault time estimation. Thus, the threshold limit should be chosen to be as small as possible, but based on the error margin of the particular device performing fault time estimation and/or other relevant quantities of the location/system (e.g., the line rating). As one concrete example, the threshold may be defined as 0.1% of the relevant line rating.

In some examples, to avoid the possibility of nuisance fault time estimation, the fault time estimation techniques described herein may be performed only when the fault detection techniques described above result in a determination that a fault has occurred. In some examples, the fault time estimation techniques described herein will utilize instantaneous power measurements in only one or two power cycles to determine dp(t)/dt and dq(t)/dt for threshold checking, depending on when a fault is detected.

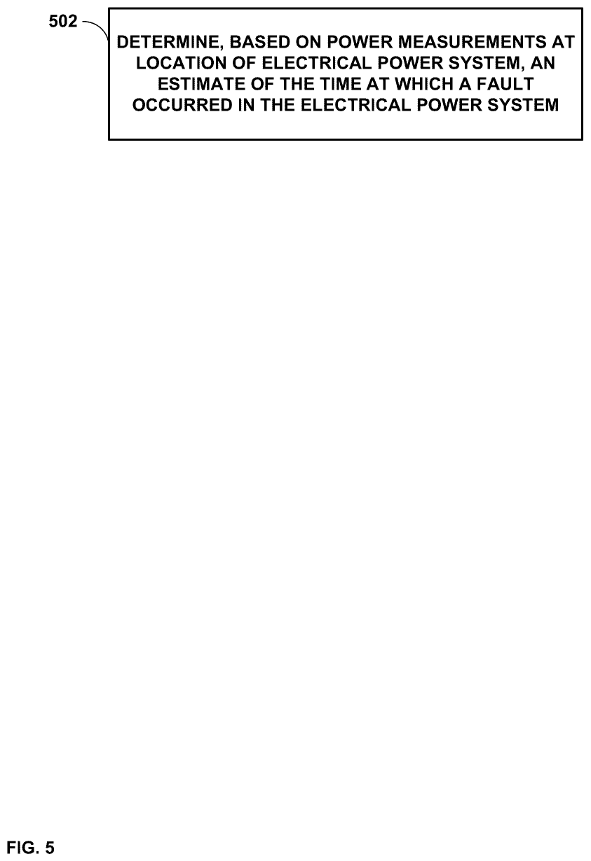

FIG. 5 is a flow diagram illustrating example operations for performing fault time estimation, in accordance with one or more aspects of the present disclosure. FIG. 5 represents only one example process for performing fault time estimation as described herein, and various other or additional operations may be used in other examples. The example operations of FIG. 5 are described below within the context of FIG. 1 and FIG. 4.

In the example of FIG. 5, a computing device having at least one processor may be configured to determine, based on power measurements at a location of an electrical power system, an estimate of the time at which a fault occurred in the electrical power system (502). For instance, the computing device may be configured to periodically obtain instantaneous active and reactive power measurements at a high frequency (e.g., 10 times per power cycle, 100 times per power cycle, 1000 times per power cycle, or some other frequency). The computing device may be further configured to retain the measurements for each particular timestep for a defined period of time, such as for one power cycle from the particular timestep. Based on the power measurements, the computing device may be configured to determine, based on the power measurements, dp(t)/dt and dq(t)/dt. That is, the computing device may be configured to determine the rate of change in active and reactive power between timesteps. If a determined value is greater than a threshold value, the computing device may be configured to determine, as the estimated fault time, the corresponding timestep.

In some examples, the computing device may be configured to determine the estimate of the time at which a fault occurred responsive to determining that a fault has occurred in the electrical power system. For example, relay 104A of system 102 may be configured to perform the operations of FIG. 4. In performing such operations, relay 104A may determine that a fault has occurred. Responsive to determining that a fault has occurred, relay 104A may determine dp(t)/dt and dq(t)/dt, where p (t) and q (t) are, respectively, the instantaneous active and reactive power as experienced by relay 104A. In some examples, these quantities may be computed using only those measurements obtained during the previous power cycle. In some examples, these quantities may be computed using measurements obtained during a longer or shorter duration. The goal of the fault time estimation is to find the timestamp at which the following condition is satisfied:

dp(t)/dt≥ϵ or dq(t)/dt≥ϵ

where ϵ is the threshold. If t_{f}^{est} is the instant at which the above condition is satisfied, then t_{f}^{est} can be determined as an estimate of the time of fault inception. Among other uses, the determined fault time estimation is important for performing the decentralized fault localization techniques provided herein below.

By using the various signatures described herein, such as positive, negative and zero sequence components and total harmonic distortions of both voltage and current waveforms measured by a relay, the fault detection techniques provided herein have the advantage of dealing with a smaller number of orders of data to be classified and ensure high accuracy in comparison with related-art techniques. Furthermore, the techniques described herein provide advantages over other related art techniques by avoiding reliance on communication, as the fault detection techniques of the present disclosure may be performed, e.g., in local relay logic during on-line operation. Another advantage of the fault detection techniques described herein is the reliance on classical power system signatures. As such, signature calculation is quite easy and often already implemented in today's power system relay logic.

In addition to fault detection, fast and accurate fault localization is also important to electrical power system protection and recovery. Detecting the location of the fault correctly may allow for efficient isolation of the fault, may inform maintenance crews, and/or may enhance the reliability of the power system. As described above, with the increased penetration of renewable DERs, especially inverter-based resources, the protection task becomes more challenging as the currents injected by these resources are limited. In addition, the nonlinear nature of power electronic-interfaced devices introduces a wide range of new challenges. Mis-operation of protective relays is of particular concern when discussing the protection of, e.g., distribution networks under massive renewable integration.

Island microgrids are poised to play a critical role in building resilient power systems, especially during restoration from natural disasters. In microgrids with 100% renewable penetration, one large source of fault currents are inverter-based resources, which can be either grid-following or grid-forming inverters. To protect the internal components of these devices, current limiters are often used to limit the output current from the inverters. Thus, fault current levels tend to be close to normal operation when the microgrid is operating in island mode. Such low current levels hinder the ability of related-art protection schemes to detect and isolate faults. In addition, the various control algorithms of inverters, which are dictated by the vendor and by the microgrid operational conditions, can make the fault response of inverters hard to characterize and detect.

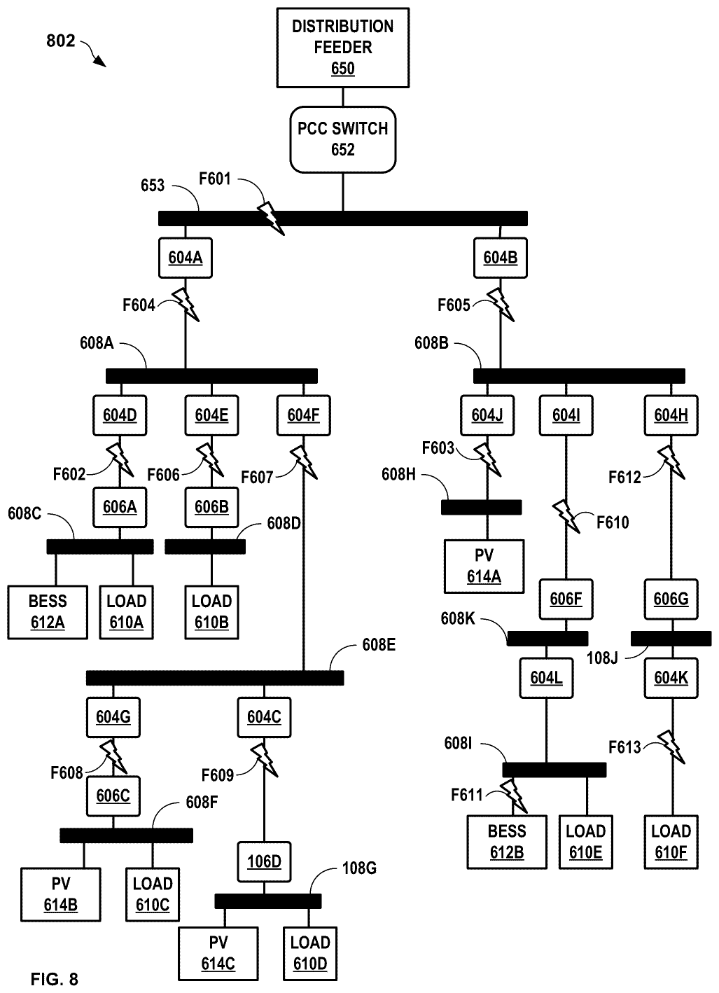

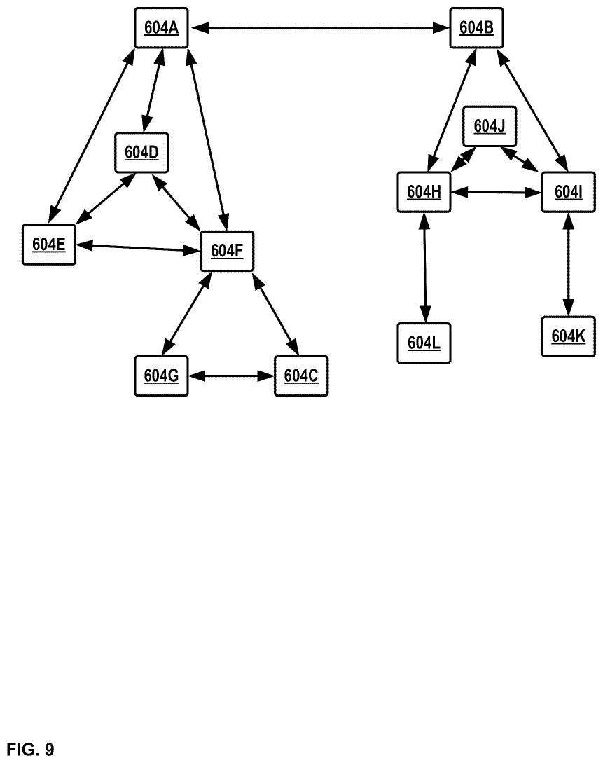

The fault localization techniques of the present disclosure provide an efficient method for fault localization in electrical power systems by using ML and decentralized localization. In contrast with some related-art approaches, the fault localization techniques of the present disclosure are effective even for systems having a high penetration of distributed energy resources, such as island microgrids with 100% renewable penetration. The fault localization techniques provided herein include the development of a comprehensive dataset generation process for power systems with significant penetrations of IBRs. The fault localization techniques also include a ML approach that differentiates downstream faults from upstream faults at each relay, based on local measurements and, in some examples, communicated measurements from neighbors. Furthermore, the present disclosure provides multiple decentralized localization approaches. One such approach is a hierarchical approach that identifies fault location-based classifiers results within decision zones. Another is a distributed approach as described below with respect to FIGS. 8 and 9.

Microgrid protection is critical in both grid-connected and islanded modes of operation. In islanded operational mode, prompt and accurate fault detection and isolation become of paramount importance to maintain system stability, especially with the lack of standards and guidelines. However, classical approaches for protection and fault detection are not efficient in microgrids due to the low fault currents that can be injected by IBRs within the microgrid. In addition, due to the short distance between buses, fault responses can propagate significantly further, making faults at different locations indistinguishable to relays. Furthermore, the various operational modes of IBRs and their numerous control architectures vary in how they respond to faults, which further increases the complexity of identifying fault signatures.

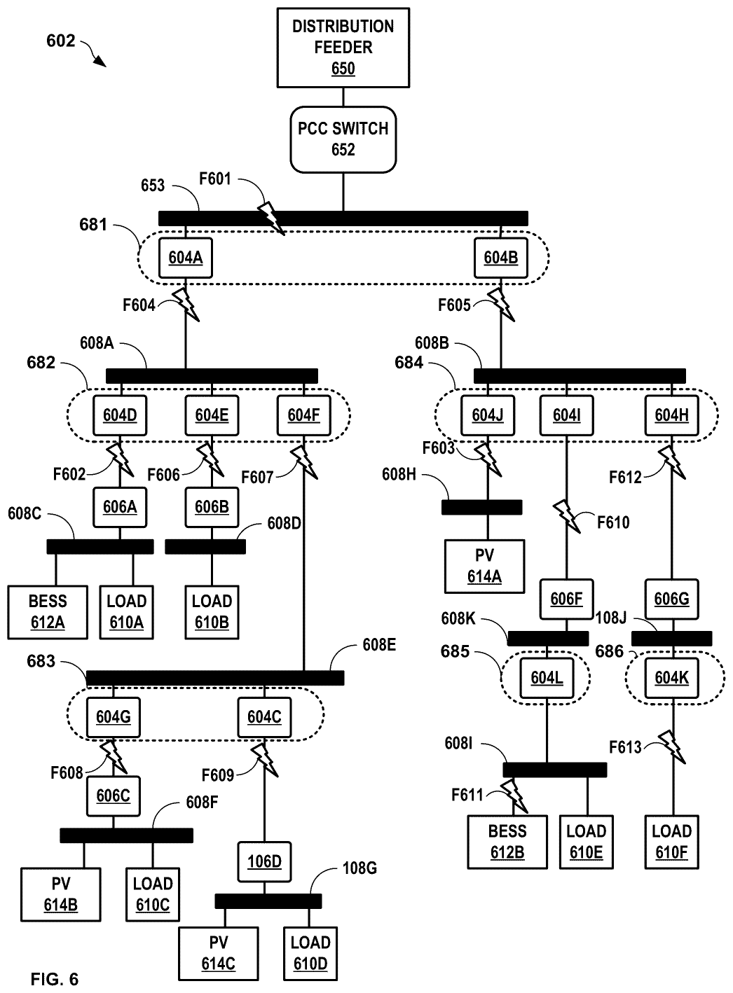

FIG. 6 is a conceptual diagram illustrating an example electrical power system (system 602) having protective relays configured to perform hierarchical fault localization in accordance with one or more aspects of the present disclosure. System 602 is generally based on Feeder 2 of the Banshee distribution network benchmark system. System 602 may represent a microgrid that includes different types of IBRs and unbalanced loads. As shown in the example of FIG. 6, system 602 includes distribution feeder 650, point of common coupling switch 652 (“PCC switch 652”), feeder bus 653, relays 604A-604L (collectively “relays 604”), transformers 606A-606G (collectively “transformers 606”), and busses 608A-608K (collectively “busses 608”).

System 602 also includes photovoltaic inverter-based resources 614A (“PV 614A”), 614B (“PV 614B”), and 614C (“PV 614C”) (collectively “PVs 614”). In the example of FIG. 6, PVs 614 operate in the grid-following mode. PVs 614 can also operate in either Volt-Var control or fixed P and Q control. The capacity of the PV systems represented by PVs 614 are 2 MVA, 1 MVA, and 0.5 MVA for PV 614A, 614B, and 614C, respectively.

As shown in the example of FIG. 6, system 602 also includes battery energy storage systems 612A (“BESS 612A”) and 612B (“BESS 612B”) (collectively “BESSs 604”). In the example of FIG. 6, the inverters for BESSs 612 are grid-forming inverters, which are essential to support the microgrid islanded operation. The inverters of BESS 612A and 612B are rated at 2 MVA and 1 MVA, respectively.

As shown in the example of FIG. 6, system 602 also includes loads 610A-610F (collectively “loads 110”). In the example of FIG. 6, loads 610B, 610D, and 610E are assumed to be balanced, while loads 610A, 610C, and 610F are assumed to be unbalanced with varying unbalancedness levels. System 602 of FIG. 6 represents only one example of a system having devices configured to perform the decentralized fault localization techniques described herein, and various other systems, having additional components, fewer components, and/or other components, may be used in accordance with the present disclosure.

In system 602, a total of 13 fault locations, denoted in FIG. 6 as F601-F613, are considered in the islanded mode. For each fault location, different relays are responsible for isolating the fault from the remaining microgrid. Table I lists the relays that are responsible for clearing (isolating) each fault.

TABLE I
Relays Responsible for Clearing Each Fault.

| Fault Location | Relay(s) |
|---|---|
| F601 | 604A, 604B |
| F602 | 604D |
| F603 | 604J |
| F604 | 604A, 604D, 604E, 604F |
| F605 | 604B, 604H, 604I, 604J |
| F606 | 604E |
| F607 | 604C, 604F, 604G |
| F608 | 604G |
| F609 | 604C |
| F610 | 604I, 604L |
| F611 | 604L |
| F612 | 604H, 604K |
| F613 | 604K |

One of the major challenges faced in the protection of microgrid networks, especially when operated in isolation from the main grid, is the unidentifiability of fault responses. That is, faults at different locations may result in very similar fault responses at a specific relay, while different actions need to be taken by the relay in each situation. The short distance between buses in microgrids can also exaggerate this issue. For example, the observed responses at relay 604L for a fault at fault location F605 and a fault at fault location F610 may be almost identical. However, relay 604L should ideally trip when a fault at fault location F610 happens but not trip when a fault at fault location F605 happens. Thus, the task of tripping only the necessary circuit breakers in response to faults is a difficult task.

Correct identification of faults and performing the correct fault isolation procedure is crucial for viability and resiliency of microgrids. Reliable operation means customers must have access to electricity unless it is truly unavoidable. In addition, when microgrids are operated based on 100% renewable energy, several corrective actions need to be taken to ensure feasible operations of the microgrid after the fault isolation, given the implemented inverter control. That being said, the post-fault restoration process is beyond the scope of the present disclosure and omitted here for brevity.

The learning aspects of the decentralized fault localization techniques described herein may be composed of three main steps: i) data generation, ii) data pre-processing, feature engineering, and labelling, and iii) classification using a machine learning classification model. In accordance with the decentralized fault localization techniques of the present disclosure, training datasets may be generated for a target electrical power system. For example, system 602 of FIG. 6 may be simulated numerous times, covering various scenarios. To provide an effective representation of fault responses, data samples that are generic and representative should be collected. In general, many factors can affect the fault response. These factors can be categorized into operational conditions and fault characteristics. The operational conditions include load demands, renewable generation availability, and mode of operation of grid-following inverters. The fault characteristics include the fault location, the fault type, and the fault impedance.

To provide representative load profiles and PV generation, a dataset of eight representative days from the measured data in S. Veda, “Eco-idea: Enhanced control and optimization of integrated distributed energy applications,” 1 2022. [Online]. (https://www.osti.gov/biblio/1843203) was used as input to simulations of system 602. During each simulation, one time instant was chosen from these days at random and the load values and the PV irradiance were used to set these parameters in the simulations. Therefore, the generated scenarios represent different operational conditions of system 602. In addition, for each scenario, the operational mode of each inverter (e.g., operational modes of BESSs 612 and PVs 614) was set to be one of Volt/VAR or fixed P and Q control at random. As a result of this variability in the scenario generation process, some scenarios exist in which the energy storage units are providing power to satisfy the loads while, in other scenarios, the PV generation is exceeding the load demand and, hence, the energy storage units are absorbing power. The state of charge of the energy storage units was not varied, as this timescale is beyond the protection relays' operational timescale.

In each simulation scenario, after setting the operational conditions of system 602 randomly, one of the 13 fault locations was selected according to a discrete uniform distribution. In addition, the type of the fault was set at random—I.e., the faulty phases (a, b, c, g), from a total of 11 possible fault types following a discrete uniform distribution. Finally, the fault resistance value was set according to:

$${z}_{fault} = 0.01 + {β}_{\frac{1}{4} , \frac{1}{4}} * ( 100 - 0.01 ) ,$$

where β_{1/4,1/4} is a realization from a Beta distribution with parameters (¼, ¼). This distribution was chosen to model both cases of low-impedance and high-impedance faults. Therefore, the generated scenarios include samples of fault scenarios that are diverse and representative of faults possible to be encountered in operation.

In each simulation, the instantaneous voltage and current values were measured at 6 KHz at each relay. These raw data include the voltage and current of all phases for the duration of the simulation, which was set to be 8.2 seconds. For each scenario, the fault was randomly placed at a point of time during the simulation period. The recorded information at all relays was then used to classify fault locations and also to generate other features that aid classifiers in identifying fault conditions.

In accordance with the decentralized fault localization techniques of the present disclosure, after collecting data measured by each relay, these measurements may be processed to obtain transformations that can serve as features to aid relays in detecting faults. Such transformations include the Park transformation, the Fourier transform, the wavelet transformation, and decomposing the voltage and current measurements intro positive-, negative-, and zero-sequence components. However, since relays will be performing these transformations in real-time (or near real-time) to detect faults, it is best to utilize only transformations that are computationally tractable and to focus on transformations that are useful in fault classification. For instance, in the performed experiments, only the positive-, negative-, and zero-sequence components of the voltage measurements were added to the signals used as input to the classifiers.

Training data was collected by extracting the measurements of 133.3̅ ms, which amounts to 8 AC cycles. This period was extracted such that the fault happens after the second cycle. Thus, measurements of two AC cycles were obtained before the fault, and six AC cycles following the fault. The total number of features for each moment in time is nine, due to the addition of the positive-, negative-, and zero-sequence components of voltage to the raw voltage and current measurements. Since the data is recorded with a 6 KHz sampling rate, the total number of features for each relay is 0.1333 s×6,000 samples/s×9 features/sample=7,200 features.

As mentioned previously, the response to various faults observed by any specific relay can be very similar to one another. This complicates the task of any single relay in operating using only its own measurements to classify fault locations. Thus, in some examples, the decentralized fault localization techniques disclosed herein may utilize a communication-based approach, wherein relays share their feature vectors with their neighboring relays. Notice that different relays may have a different number of neighbors, and hence, in such examples there will be a varying total number of features at each relay, depending on how many neighbors share their data with it.

It bears acknowledgement that an inherent asynchronicity exists among distributed relays. This includes variations in fault detection time, decision-computation duration, and communication latency. Collectively, these elements highlight the need for a synchronization process to align distributed decisions within a given neighborhood. To address these potential issues, the techniques of the present disclosure include a “hold-and-wait” strategy to synchronize these relay decisions. Specifically, after calculating information to be transmitted to its neighbors, such as a feature vector or a binary fault direction classification, a relay may hold its decision and enter a predefined waiting period. As a concrete example, 1/6 cycle may be used (equivalent to 2.8 milliseconds in a 60 Hz system). This brief but critical pause may accommodate for the discrepancies in neighboring relays, thereby mitigating the risks associated with asynchronous decision-making. The wait time may be specific to each system, but it should typically be small, because the distributed techniques provided herein require synchronization only with neighboring relays.

Herein, it is assumed that any two relays are neighbors if the electric path between them has no other relays. For example, in system 602, relay 604L has only one neighbor, which is relay 6041, while relay 604F is a neighbor to relays 604A, 604C, 604D, 604E, and 604G. Therefore, the total number of features used in the classifier at relay 604F will be 7,200 local features plus 36,000 features shared by neighbors, which leads to a total of 43,200 features. On the other hand, relay 604L will process only 14,400 features in its own classifier.

In accordance with the decentralized fault localization techniques of the present disclosure, after each relay has obtained measurements and processed measurements from its neighbors, it is tasked with categorizing each fault according to the fault's location relative to the relay. In other words, each fault is classified by each relay as either downstream or upstream from the relay location. For example, the classifier located at relay 604L aims to classify a fault at fault location F611 as a downstream fault while all other faults should be classified as upstream faults. Similarly, the classifier located at relay 604A should classify faults at fault locations F602, F604, F606, F607, F608, and F609 as downstream faults while the remaining faults should be classified as upstream faults. Therefore, the classifier at each relay is simply a binary classifier, where the labels are added to the training data during pre-processing.

As mentioned above, each classifier is binary, indicating if the fault is downstream or upstream from the relay location. Therefore, the performance of each relay can be assessed by measuring metrics such as accuracy, precision, recall, and F1-score. For precision and recall, it is assumed that the downstream faults correspond to the ‘1’ class, while upstream faults correspond to the ‘0’ class. Note that the performance of each relay is assessed independently, and the balancedness of the data samples at each relay is different. For example, only one of every thirteen samples will be positive for relay 604L, while the data will be more balanced for relays 604A and 604B. This imbalance in data may challenge the classification task, but addressing this specific aspect is beyond the scope of this disclosure and omitted for brevity.

Considering the way in which the local classifiers are designed, the location of the faults cannot be completely determined by any single classifier decision in many scenarios. Therefore, in accordance with the decentralized fault localization techniques described herein, the classification results of relays may be combined to determine the fault location. In general, the twelve relay classifiers will provide an estimate on whether each fault is upstream or downstream from each relay. Combining the results of these classifiers, the location of the fault can be detected. For example, a fault at fault location F610 should be classified as upstream fault in all classifiers except the classifiers at relays 604B and 6041, which should have this fault classified as downstream fault. However, determining the fault location based on all relay classifiers (12 in the example of FIG. 6) requires a centralized operation, which can be challenging to perform in microgrids and other systems.

Therefore, the fault localization techniques provided herein include decentralized approaches to determine the location of faults, based on communication between neighboring relays. In the example of FIG. 6, this decentralized approach is hierarchical, based on partitioning the microgrid into multiple decision zones. Each decision zone has a group of relays that combine the results of the classifiers within the decision zone to identify fault location and/or to identify the decision zone that needs to be checked. For illustration purposes, the decision zones are depicted in FIG. 6 as decision zones 681, 682, 683, 684, 685, and 686.

For each decision zone, upon obtaining the classification results, a decision is taken regarding the fault location. For example, in Table II, the decisions that are taken based on the relays' classifiers in decision zone 681 are listed. If both relays 604A and 604B detect that the fault is upstream from them, then the fault is declared to be fault location F601. If only the classifier at relay 604A classifies the fault as downstream, then the relays in decision zone 682 are informed that the fault localization task is passed down to them. Similarly, if only relay 604B classifies the fault as a downstream fault, the relays in decision zone 684 are informed. Notice that, because the classifiers can have classification errors, there may be a scenario where both relays classify the fault as a downstream fault. To address this, a maximum likelihood estimate is designed that uses the statistics of the classifiers. The details of this are not included here in the interest of brevity.

TABLE II
Decision rules for Decision Zone #1

| 604A | 604B | Decision |
|---|---|---|
| 0 | 0 | Fault location 1 |
| 0 | 1 | DZ 684 |
| 1 | 0 | DZ 682 |
| 1 | 1 | Inadmissible |

The efficacy of the hierarchical fault localization techniques described herein were validated as follows. Support vector machine (SVM) classifiers trained as described above were used at all relays. The implementation was done using the sklearn function (from F. Pedregosa, et al., “Scikit-learn: Machine learning in Python,” Journal of Machine Learning Research, vol. 12, pp. 2825-2830, 2011) using the ‘rbf’ kernel with the value of the regularizer chosen between 10 and 100. First, the performance of each classifier was assessed separately. Then, the accuracy of each decision zone was presented.

As discussed before, the classifier at each relay is a binary classifier that aims to differentiate between upstream and downstream faults. For each classifier, the performance was assessed based on its accuracy, precision, and recall. These measures are essential to fully assess the performance of each relay.

The training data generation process described herein was used to generate a total of 1,000 fault scenarios. Then, these samples were divided into 700 samples for training and 300 samples for testing. In addition, due to the high-dimensional nature of the data, principal component analysis (PCA) was used as a dimensionality reduction technique before passing the data to the classifiers. To ensure fair assessment of the performance, the PCA was trained only on the training samples. The dimensionality reducing matrix that resulted from training the PCA was also used in testing the online operation of the provided techniques. Through the use of PCA, the number of features to be provided to the SVM classifiers was reduced in all data samples to 300. Thus, all SVM classifiers have the same size of inputs.

In Table III, the performance of each classifier is presented. Note that, in the data generation process, the probability of each fault is 1/13. Thus, some of the classifiers have unbalanced data in training, i.e., the ratio of positive samples is much less than negative samples. This emphasizes the importance of metrics such as recall and precision.

TABLE III
Performance of each relay classifier on testing samples.

| Relay | Precision | Recall | Accuracy |
|---|---|---|---|
| 604A | 87.10% | 69.41% | 78.77% |
| 604B | 77.38% | 80.25% | 80.45% |
| 604C | 72.22% | 76.47% | 94.97% |
| 604D | 97.96% | 100% | 99.81% |
| 604E | 100% | 100% | 100% |
| 604F | 88.89% | 66.67% | 88.83% |
| 604G | 59.09% | 72.22% | 92.18% |
| 604H | 27.08% | 54.17% | 74.30% |
| 604I | 81.81% | 93.10% | 95.53% |
| 604J | 70.00% | 70.00% | 96.64% |
| 604K | 100% | 100% | 100% |
| 604L | 100% | 60.53% | 87.70% |

The identification of the fault location is based on the hierarchical approach using the decision zones defined previously. The hierarchical approach starts from a decision zone, then other decision zones are involved as appropriate, based on the results of the classifiers, until the location of the fault is identified. Below, the performance of each decision zone is assessed, which measures the accuracy of the overall approach.

The number of possible outcomes for each decision zone depends on the number of relays within the decision zone. For example, decision zones 682 and 684 encompass three relays, and hence, the number of possible outcomes is eight. Therefore, an accurate decision for these two decision zones requires all three relays within the zone to correctly identify whether the fault is upstream or downstream from each relay. In Table IV, the results of accuracy of each decision zone is presented.

TABLE IV
Accuracy of decisions in each zone.

| Decision Zone | # of Relays | Accuracy |
|---|---|---|
| DZ 681 | 2 | 0.761 |
| DZ 682 | 3 | 0.826 |
| DZ 683 | 2 | 0.92 |
| DZ 684 | 3 | 0.737 |
| DZ 685 | 1 | 0.95 |
| DZ 686 | 1 | 0.993 |

The results of the hierarchical fault localization accuracy are comparable to those of other, related-art techniques. However, the techniques of the present disclosure address two additional challenges. First, all the scenarios considered were from island operation with 100% renewable penetration, which leads to a reduced magnitude of fault currents and significant nonlinearity in fault responses. Second, the scenarios used contain many high-impedance fault scenarios, which are challenging to detect and classify because they may not cause noticeable change in the voltage and current levels in the microgrid.

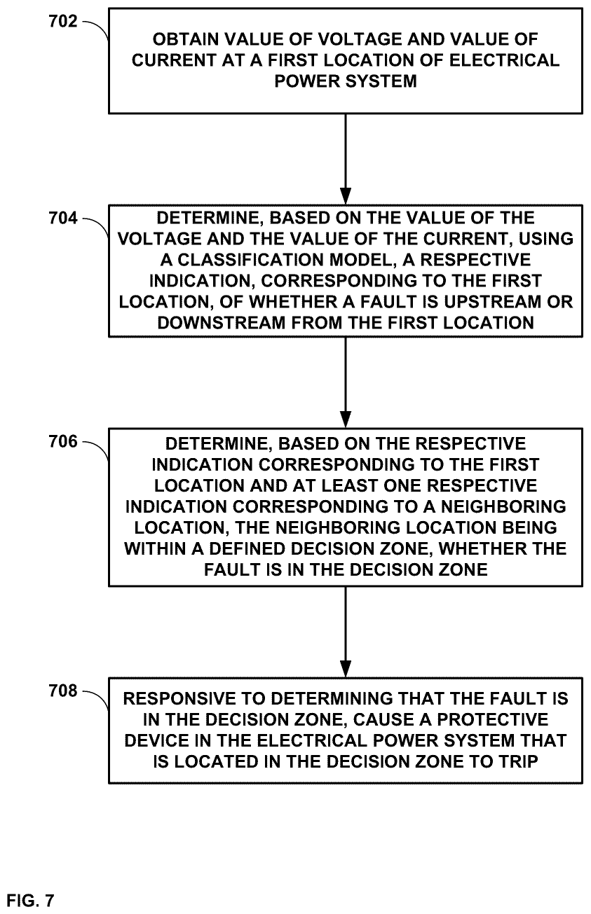

FIG. 7 is a flow diagram illustrating example operations for performing hierarchical fault localization, in accordance with one or more aspects of the present disclosure. FIG. 7 represents only one example process for performing hierarchical fault localization as described herein, and various other or additional operations may be used in other examples. The example operations of FIG. 7 are described below within the context of FIG. 6.

In the example of FIG. 7, a computing device having at least one processor may be configured to measure, receive, or otherwise obtain a value of a voltage and a value of a current at a first location of an electrical power system (702). For example, relay 604A of system 602 may be configured to measure the instantaneous voltage and current at relay 604A. Typical protective relays may measure the instantaneous voltage and current at a relatively high frequency, such as 1024 measurements per power cycle. In some examples, the computing device may retain voltage and current values for a time period, such as for one minute, for one second, for 10 power cycles, or for some other period.

In the example of FIG. 7, the computing device may be further configured to determine, based on the value of the voltage and the value of the current, using a classification model, a respective indication, corresponding to the first location, of whether a fault is upstream or downstream from the first location (704). In some examples, the classification model may be an SVM-based classification model (or classifier). For example, relay 604A may utilize a classification model, generated as detailed above with respect to FIG. 6, that receives, as features, the instantaneous voltage of each phase, the instantaneous current of each phase, and the positive, negative, and zero sequence voltage. Each time at which the measurements are collected and the features determined may be referred to herein as a timestep. The classification model may receive the features and output a binary indication—either indicating that the fault is upstream of relay 604A or that the fault is downstream of relay 604A. In some examples, the classification model may receive a respective set of features for multiple timesteps. For example, relay 604A may receive features corresponding to timesteps in eight power cycles. Which eight power cycles are provided to the classification model may be based on the estimated fault time resulting from the fault time estimation techniques described herein, such that features from two power cycles before the estimated fault time and six power cycles after the estimated fault time may be provided. In some examples, the classification model may be configured to receive features for more or fewer or different timesteps. In some examples, such as where the number of features is very large, the set of features received by the classification model may be the result of performing PCA on the large number of features.

In some examples, the computing device may determine the respective indication of whether a fault is upstream or downstream from the first location based additionally on information received from neighboring devices. For instance, relay 604A may receive features from relays 604B, 604D, 604E, and/or 604F, and determine the indication of whether the fault is upstream or downstream of relay 604A based additionally on such received features. In some examples, the computing device may also output information for use by neighboring devices. For instances, relay 604A may output features including or derived from the value of the voltage and the value of the current, for use by relays 604B, 604D, 604E, and/or 604F in their own respective determination of whether the fault is downstream or upstream of their respective location. In some examples, the computing device may be further configured to perform one or more operations to ensure proper synchronicity between neighboring devices and avoid communications failures. As one concrete example, a computing device may be configured to undergo a delay prior to outputting its features for use by neighboring devices (e.g., in determining whether a fault is downstream of upstream of such neighboring devices). In various examples, this delay may be pre-determined or may be dynamic. By delaying the output of its determination, the computing device may better ensure that neighboring devices have had time to recognize that a fault exists and thus be ready to perform fault localization techniques as described herein.

In the example of FIG. 7, the computing device may be further configured to determine, based on the respective indication corresponding to the first location and at least one respective indication corresponding to a neighboring location, the neighboring location being within a defined decision zone that includes the first location, whether the fault is in the decision zone (706). For example, relay 604A may receive or otherwise obtain an indication (e.g., from relay 604B) that indicates the fault is upstream of relay 604B or that the fault is downstream of relay 604B. Based on the indication determined by relay 604A and the indication corresponding to relay 604B, relay 604A may determine whether the fault is in Decision Zone 681. In some examples, the computing device may be further configured to output an indication of its determination whether the fault is in the decision zone. This indication may be used by neighboring devices. In some examples, the computing device may be further configured to perform one or more operations to ensure proper synchronicity between neighboring devices and avoid communications failures. As one concrete example, a computing device may be configured to undergo a delay prior to outputting its determination of whether the fault is upstream or downstream for use by neighboring devices (e.g., in determining whether a fault is in the neighboring devices' decision zone). In various examples, this delay may be pre-determined or may be dynamic. By delaying the output of its determination, the computing device may better ensure that neighboring devices have had time to recognize that a fault exists and thus be ready to perform fault localization techniques as described herein.

In the example of FIG. 7, the computing device may be further configured to cause, responsive to determining that the fault is in the decision zone, a protective device in the electrical power system that is located in the decision zone to trip (708). For example, relay 604A may, responsive to determining that the fault is in Decision Zone 681, cause relay 604A to trip a circuit breaker.

In some examples, the operations shown in the example of FIG. 7 may be performed responsive to various triggers. As one example, the operations of FIG. 7 may be performed responsive to the computing device determining that a fault has occurred. For instance, relay 604A may be further configured to perform the operations shown in the example of FIG. 4 and relay 604A may perform operations 702, 704, 706, and/or 708 as part of performing operation 408. As another example, the operations of FIG. 7 may be performed responsive to the computing device receiving, from a neighboring device in another decision zone, an indication that the fault is not in the neighboring device's decision zone. In some such examples, the computing device may be further configured to output an indication to other neighboring devices in its decision zone, thereby causing such neighboring devices to take one or more actions, such as performing the operations of FIG. 7. As another example, the operations of FIG. 7 may be performed responsive to the computing device receiving, from a neighboring device in the same decision zone, an indication that a fault was detected.

In some examples, the computing device may be configured to, responsive to determining that a fault has occurred outside of the decision zone, output an indication of this determination. This indication may be received and used by, e.g., neighboring devices not in the decision zone. For instance, relay 604A may, responsive to determining that the fault is not in Decision Zone 681, output an indication of this determination. This indication may be received by, e.g., relays 604D, 604E, and/or 604F. In some examples, responsive to determining whether the fault is in the decision zone, the computing device may not perform any further operations. That is, in some examples a computing device may be configured to perform operations 702, 704, and 706, but not perform operation 708.

FIG. 8 is a conceptual diagram illustrating an example electrical power system (system 802) having protective relays configured to perform distributed fault localization in accordance with one or more aspects of the present disclosure. System 802 is essentially the same as system 602 as described in the context of FIG. 6. However, in the example of FIG. 8, relays 604 are configured to perform fault localization in a distributed fashion as detailed below.

The fault localization approach described with respect to FIG. 8 involves minimal communication requirements. The fault localization problem is generally challenging for distributed algorithms, where each relay has access only to its own measurements. While observing from a single relay, system fault responses for different locations may appear indistinguishable. To circumvent this issue, the techniques of the present disclosure solve the fault localization problem by using distributed relay classification-which produces a binary output indicating whether the fault location is upstream or downstream relative to the relay's position in the network, and local relay cooperation—wherein each relay shares its binary classification decision solely with neighboring relays to collaboratively determine the presence of a fault in the neighborhood. The first process simplifies the multi-class problem to a relative simple two-class problem. More importantly, it improves the relay's observability over the converted two-class problem. The second process serves as a complementary step, integrating the distributed decisions for precise fault location.

In the distributed fault localization techniques provided herein, when a protective relay or other device having at least one processor detects a system fault (e.g., using the fault detection techniques described herein), its fault direction classifier is triggered. Upon determining the fault direction from the gathered data, the relay enters a ‘hold-and-wait’ mode, synchronizing with the decisions of neighboring relays. Subsequently, the relay assesses if a fault has occurred within its neighborhood and accordingly produces the circuit breaker signal. Details of this processor are described below with reference to FIG. 8.

In order to formulate the fault direction problem, it is necessary to obtain the relationship between the fault location and the fault direction from a relay's perspective. Such information is contingent upon the specific system network topology. For system 802 as shown in FIG. 8, Table V provides the conversion from specific fault locations to their corresponding relative fault direction for each relay.

TABLE V
Fault Direction

| | 604A | 604B | 604C | 604D | 604E | 604F | 604G | 604H | 604I | 604J | 604K | 604L |
|---|---|---|---|---|---|---|---|---|---|---|---|---|
| F601 | 0 | 0 | 0 | 0 | 0 | 0 | 0 | 0 | 0 | 0 | 0 | 0 |
| F602 | 1 | 0 | 0 | 1 | 0 | 0 | 0 | 0 | 0 | 0 | 0 | 0 |
| F603 | 0 | 1 | 0 | 0 | 0 | 0 | 0 | 0 | 0 | 1 | 0 | 0 |
| F604 | 1 | 0 | 0 | 0 | 0 | 0 | 0 | 0 | 0 | 0 | 0 | 0 |
| F605 | 0 | 1 | 0 | 0 | 0 | 0 | 0 | 0 | 0 | 0 | 0 | 0 |
| F606 | 1 | 0 | 0 | 0 | 1 | 0 | 0 | 0 | 0 | 0 | 0 | 0 |
| F607 | 1 | 0 | 0 | 0 | 0 | 1 | 0 | 0 | 0 | 0 | 0 | 0 |
| F608 | 1 | 0 | 0 | 0 | 0 | 1 | 1 | 0 | 0 | 0 | 0 | 0 |
| F609 | 1 | 0 | 1 | 0 | 0 | 1 | 0 | 0 | 0 | 0 | 0 | 0 |
| F610 | 0 | 1 | 0 | 0 | 0 | 0 | 0 | 1 | 0 | 0 | 0 | 0 |
| F611 | 0 | 1 | 0 | 0 | 0 | 0 | 0 | 1 | 0 | 0 | 0 | 1 |
| F612 | 0 | 1 | 0 | 0 | 0 | 0 | 0 | 0 | 1 | 0 | 0 | 0 |
| F613 | 0 | 1 | 0 | 0 | 0 | 0 | 0 | 0 | 1 | 0 | 1 | 0 |

The training process for the fault direction classifier may include data collection, data preprocessing, SVM classifier initialization, and SVM classifier training. The training data sample may include four cycles of both voltage and current magnitudes, where the first cycle data is collected before the fault event, and the remaining three-cycle data captures the post-fault response. This dataset is then standardized to ensure consistent scaling among features. To reduce the computational complexity and mitigate the risk of overfitting, dimensionality reduction is performed using the principal component analysis (PCA) technique. Thereafter, w the hyperparameters for the SVM model are initialized, including the mis-classification parameter and the kernel function selection.

In general, the relays exhibit a greater number of upstream data samples than downstream samples. To address this unbalanced data issue, a greater weight may be allocated to the downstream class, allowing the model to give more importance to its samples during training and reduce bias towards the upstream class. To enhance the model generalizability, the 5-fold cross-validation method may be employed to reduce the model sensitivity to the partitioning between training and test data. After training a model, the model undergoes validation using the offline-line testing data. If the model fails to meet predefined stopping criteria based on validation performance, an iterative process of hyperparameter tuning and model training may be repeated.

As suggested by Table V, fault localization requires a consensus on directions from all relays. However, such centralized decision-making process is notably sensitive to the decisions of individual relays, rendering it susceptible to vulnerabilities. This is extremely challenging for a large system. In contrast, the distributed approach provided herein emphasizes the decisions of local relays for fault localization. For instance, within system 802 as shown in FIG. 8, a fault at fault location F604 is validated by the combined decisions of relays 604A (downstream), 604D (upstream), 604E (upstream), and 604F (upstream). A comprehensive summary of fault locations and their corresponding local relay decisions can be found in Table VI, below.

TABLE VI
Fault Localization Using Local Fault Direction Estimates

| | 604A | 604B | 604C | 604D | 604E | 604F | 604G | 604H | 604I | 604J | 604K | 604L |
|---|---|---|---|---|---|---|---|---|---|---|---|---|
| F601 | 0 | 0 | | | | | | | | | | |
| F602 | | | | 1 | | | | | | | | |
| F603 | | | | | | | | | | 1 | | |
| F604 | 1 | | | 0 | 0 | 0 | | | | | | |
| F605 | | 1 | | | | | | 0 | 0 | 0 | | |
| F606 | | | | | 1 | | | | | | | |
| F607 | | | 0 | | | 1 | 0 | | | | | |
| F608 | | | | | | | 1 | | | | | |
| F609 | | | 1 | | | | | | | | | |
| F610 | | | | | | | | 1 | | | | 0 |
| F611 | | | | | | | | | | | | 1 |
| F612 | | | | | | | | | 1 | | 0 | |
| F613 | | | | | | | | | | | 1 | |

For distributed fault localization in accordance with the techniques described herein, each relay determines whether a fault has occurred in its immediate vicinity. To achieve this, a relay exchanges the fault direction decision with its neighboring relays. FIG. 9 is a conceptual diagram illustrating communication among relays 604 when performing the distributed fault localization techniques described with respect to FIG. 8.

Numerical simulations of system 802 were performed on MATLAB/Simulink. To represent comprehensive microgrid fault scenarios, simulations were conducted using various parameters, such as fault type, fault location, fault impedance, load condition, solar irradiance, and inverter type. The load profiles and PV generation were generated from real measured data provided in the literature. During the simulation, each relay continuously measured three-phase voltage and current at a sampling frequency of 6 kHz. For every fault scenario encountered, each relay collected four cycles of three-phase voltage and current magnitudes, where the first cycle data was collected before the fault event, and the remaining three-cycle data (corresponding to 0.05 seconds) captured the post-fault response. In total, data was collected from 1000 fault scenarios, of which 800 scenarios were used for learning algorithm training and the rest 200 scenarios were used for testing.

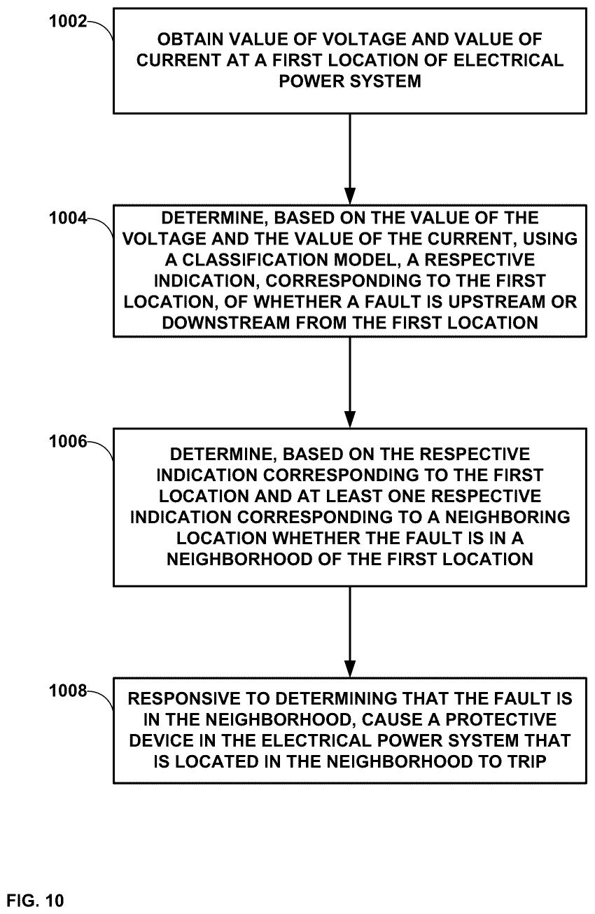

FIG. 10 is a flow diagram illustrating example operations for performing distributed fault localization in accordance with one or more aspects of the present disclosure. FIG. 10 represents only one example process for performing distributed fault localization as described herein, and various other or additional operations may be used in other examples. The example operations of FIG. 10 are described below within the context of FIG. 8.

In the example of FIG. 10, a computing device having at least one processor may be configured to measure, receive, or otherwise obtain a value of a voltage and a value of a current at a first location of an electrical power system (1002). For example, relay 604A of system 802 may be configured to measure the instantaneous voltage and current at relay 804A. Typical protective relays may measure the instantaneous voltage and current at a relatively high frequency, such as 1024 measurements per power cycle. In some examples, the computing device may retain voltage and current values for a time period, such as for one minute, for one second, for 10 power cycles, or for some other period.

In the example of FIG. 10, the computing device may be further configured to determine, based on the value of the voltage and the value of the current, using a classification model, a respective indication, corresponding to the first location, of whether a fault is upstream or downstream from the first location (1004). In some examples, the classification model may be an SVM-based classification model (or classifier). For example, relay 1004A may utilize a classification model, generated as detailed above with respect to FIG. 8, that receives, as features, the instantaneous voltage magnitude of each phase and the instantaneous current magnitude of each phase. Each time at which the measurements are collected may be referred to herein as a timestep. The classification model may receive the features and output a binary indication-cither indicating that the fault is upstream of relay 604A or that the fault is downstream of relay 604A. In some examples, the classification model may receive a respective set of features for multiple timesteps. For example, relay 604A may receive features corresponding to timesteps in four power cycles. Which four power cycles are provided to the classification model may be based on the estimated fault time resulting from the fault time estimation techniques described herein, such that features from one power cycle before the estimated fault time and three power cycles after the estimated fault time may be provided. In some examples, the classification model may be configured to receive features for more or fewer or different timesteps. In some examples, the features may be standardized to ensure consistent scaling. In some examples, such as where the number of features is very large, the set of features received by the classification model may be the result of performing PCA on the large number of features.

In some examples, the computing device may determine the respective indication of whether a fault is upstream or downstream from the first location based additionally on information received from neighboring devices. For instance, relay 604A may receive features from relays 604B, 604D, 604E, and/or 604F, and determine the indication of whether the fault is upstream or downstream of relay 604A based additionally on such received features. In some examples, the computing device may also output information for use by neighboring devices. For instances, relay 604A may output features including or derived from the value of the voltage and the value of the current, for use by relays 604B, 604D, 604E, and/or 604F in their own respective determination of whether the fault is downstream or upstream of their respective location. In some examples, the computing device may be further configured to perform one or more operations to ensure proper synchronicity between neighboring devices and avoid communications failures. As one concrete example, a computing device may be configured to undergo a delay prior to outputting its features for use by neighboring devices (e.g., in determining whether a fault is downstream of upstream of such neighboring devices). In various examples, this delay may be pre-determined or may be dynamic. By delaying the output of its determination, the computing device may better ensure that neighboring devices have had time to recognize that a fault exists and thus be ready to perform fault localization techniques as described herein.

In the example of FIG. 10, the computing device may be further configured to determine, based on the respective indication corresponding to the first location and at least one respective indication corresponding to a neighboring location, whether the fault is in a neighborhood of the first location (1006). For example, relay 604A may receive or otherwise obtain an indication (e.g., from relays 604B, 604D, 604E and/or 604F) that indicates the fault is upstream or downstream of a neighboring relay. Based on the indication determined by relay 604A and the indication corresponding to neighboring relays, relay 604A may determine whether the fault is in the neighborhood of relay 604A. In some examples, the computing device may be further configured to perform one or more operations to ensure proper synchronicity between neighboring devices and avoid communications failures. As one concrete example, a computing device may be configured to undergo a delay prior to outputting its determination of whether the fault is upstream or downstream for use by neighboring devices (e.g., in determining whether a fault is in the neighboring devices' neighborhood). In various examples, this delay may be pre-determined or may be dynamic. By delaying the output of its determination, the computing device may better ensure that neighboring devices have had time to recognize that a fault exists and thus be ready to perform fault localization techniques as described herein.

In the example of FIG. 10, the computing device may be further configured to cause, responsive to determining that the fault is in the neighborhood, a protective device in the electrical power system that is in the neighborhood to trip (1008). For example, relay 604A may, responsive to determining that the fault is in its neighborhood, cause relay 604A to trip a circuit breaker.

In some examples, the operations shown in the example of FIG. 10 may be performed responsive to various triggers. As one example, the operations of FIG. 10 may be performed responsive to the computing device determining that a fault has occurred. For instance, relay 604A may be further configured to perform the operations shown in the example of FIG. 4 and relay 604A may perform operations 1002, 1004, 1006, and/or 1008 as part of performing operation 408. In some examples, responsive to determining whether the fault is in the neighborhood, the computing device may not perform any further operations. That is, in some examples a computing device may be configured to perform operations 1002, 1004, and 1006, but not perform operation 1008.

Protection of microgrids with 100% penetration from IBRs remains a challenge to the adoption of microgrids in future power networks. The present disclosure provides an ML-based approach to identify fault locations within microgrids. A comprehensive dataset of fault scenarios was generated by varying operational conditions as well as fault characteristics. Then, an ML approach was disclosed that simplifies the task of each relay into a binary classification. Then, decentralized approaches were provided to localize the faults based on the decisions of the simple classifiers at the relays. While tackling very challenging scenarios, the techniques of the present disclosure showed performance levels that are close to or above related-art approaches.

At least some of the techniques of the present disclosure may be additionally or alternatively described by one or more of the following examples:

Example 1. A device comprising: at least one processor configured to: determine, based on a value of a voltage and a value of a current at a location of an electrical power system, a plurality of voltage features and a plurality of current features corresponding to the location; determine, based on the plurality of voltage features and the plurality of current features, using a classification model, whether a fault has occurred in the electrical power system; and responsive to determining that a fault has occurred, causing a protective device in the electrical power system to trip.

Example 2. The device of example 1, wherein: determining the plurality of voltage features comprises: determining, based on a first value of the voltage corresponding to a first phase at the location, a second value of the voltage corresponding to a second phase at the location, and a third value of the voltage corresponding to a third phase at the location, a positive sequence voltage corresponding to the location, a negative sequence voltage corresponding to the location, and a zero sequence voltage corresponding to the location; and determining, for each of the first phase, the second phase, and the third phase, a respective total harmonic distortion of the respective voltage; and determining the plurality of current features comprises: determining, based on a first value of the current corresponding to the first phase, a second value of the current corresponding to the second phase, and a third value of the current corresponding to the third phase, a positive sequence current corresponding to the location, a negative sequence current corresponding to the location, and a zero sequence current corresponding to the location; and determining, for each of the first phase, the second phase, and the third phase, a respective total harmonic distortion of the respective current.

Example 3. The device of example 2, wherein: the plurality of voltage features further comprises the first value of the voltage, the second value of the voltage, and the third value of the voltage; and the plurality of current features further comprises the first value of the current, the second value of the current, and the third value of the current.

Example 4. The device of any of examples 1-3, wherein the classification model comprises a support vector machine (SVM)-based classification model.

Example 5. The device of any of examples 1-4, wherein the at least one processor is further configured to: responsive to determining that a fault has occurred, determine, based on power measurements at the location, an estimate of a time at which the fault occurred.

Example 6. The device of example 5, wherein determining the estimate of the time at which the fault occurred comprises: determining, as the estimate of the time, a time at which at least one of (i) a rate of change of an active power at the location or (ii) a rate of change of a reactive power at the location exceeded a threshold rate of change.

Example 7. The device of any of examples 1-6, wherein the device comprises a protective relay and causing the protective device to trip comprises tripping a circuit breaker of the protective relay.

Example 8. A device comprising: at least one processor configured to: determine, based on a value of a voltage and a value of a current at a first location of an electrical power system, using a classification model, a respective indication, corresponding to the first location, of whether a fault is upstream or downstream from the first location; determine, based on the respective indication corresponding to the first location and a respective indication corresponding to a neighboring location, whether the fault is in a neighborhood of the first location; and responsive to determining that the fault is in a neighborhood of the first location, causing a protective device in the electrical power system that is in the neighborhood to trip.

Example 9. The device of example 8, further comprising outputting the respective indication corresponding to the first location.

Example 10. The device of example 9, wherein outputting the respective indication comprises: responsive to determining the respective indication corresponding to the first location, waiting a defined period of time; and outputting the respective indication corresponding to the first location after waiting the defined period of time.

Example 11. The device of any of examples 8-10, wherein: the value of the voltage comprises a first value of the voltage corresponding to a first phase at the location; the value of the current comprises a first value of the current corresponding to the first phase; and determining the respective indication corresponding to the first location is further based on a second value of the voltage corresponding to a second phase at the location, a second value of the current corresponding to the second phase, a third value of the voltage corresponding to a third phase at the location, and a third value of the current corresponding to the third phase.

Example 12. The device of example 11, wherein: determining the respective indication corresponding to the first location further comprises determining, based on the first value of the voltage, the second value of the voltage, and the third value of the voltage, a positive sequence voltage corresponding to the location, a negative sequence voltage corresponding to the location, and a zero sequence voltage corresponding to the location; and determining the respective indication corresponding to the first location is further based on the positive sequence voltage, the negative sequence voltage, and the zero sequence voltage.

Example 13. The device of any of examples 8-12, wherein the classification model comprises a support vector machine (SVM)-based classification model.

Example 14. The device of any of examples 8-13, wherein the device comprises a protective relay and causing the protective device to trip comprises tripping a circuit breaker of the protective relay.

Example 15. A device comprising: at least one processor configured to: determine, based on a value of a voltage and a value of a current at a first location of an electrical power system, using a classification model, a respective indication, corresponding to the first location, of whether a fault is upstream or downstream from the first location; determine, based on the respective indication corresponding to the first location and a respective indication corresponding to a neighboring location, the neighboring location being within a decision zone that includes the first location whether the fault is the decision zone; and responsive to determining that the fault is in the decision zone, causing a protective device in the electrical power system that is in the decision zone to trip.

Example 16: The device of example 15, wherein the at least one processor is further configured to: responsive to determining that the fault is not in the decision zone, output an indication of such determination.

Example 17. The device of any of examples 15-16, wherein the classification model comprises a support vector machine (SVM)-based classification model.

Example 18. The device of any of examples 15-17, wherein the device comprises a protective relay and causing the protective device to trip comprises tripping a circuit breaker of the protective relay.

Example 19. A method comprising any of the operations of Examples 1-18.

In one or more examples, the techniques described herein may be implemented in hardware, software, firmware, or any combination thereof. If implemented in software, the functions may be stored on or transmitted over, as one or more instructions or code, a computer-readable medium and executed by a hardware-based processing unit. Computer-readable media may include computer-readable storage media, which corresponds to a tangible medium such as data storage media, or communication media, which includes any medium that facilitates transfer of a computer program from one place to another, e.g., according to a communication protocol. In this manner, computer-readable media generally may correspond to (1) tangible computer-readable storage media, which is non-transitory or (2) a communication medium such as a signal or carrier wave. Data storage media may be any available media that can be accessed by one or more computers or one or more processors to retrieve instructions, code and/or data structures for implementation of the techniques described in this disclosure. A computer program product may include a computer-readable storage medium.

By way of example, and not limitation, such computer-readable storage media can comprise RAM, ROM, EEPROM, CD-ROM or other optical disk storage, magnetic disk storage, or other magnetic storage devices, flash memory, or any other medium that can be used to store desired program code in the form of instructions or data structures and that can be accessed by a computer. Also, any connection is properly termed a computer-readable medium. For example, if instructions are transmitted from a website, server, or other remote source using a coaxial cable, fiber optic cable, twisted pair, digital subscriber line (DSL), or wireless technologies such as infrared, radio, and microwave, then the coaxial cable, fiber optic cable, twisted pair, DSL, or wireless technologies such as infrared, radio, and microwave are included in the definition of medium. It should be understood, however, that computer-readable storage media and data storage media do not include connections, carrier waves, signals, or other transient media, but are instead directed to non-transient, tangible storage media. Disk and disc, as used herein, includes compact disc (CD), laser disc, optical disc, digital versatile disc (DVD), floppy disk and Blu-ray disc, where disks usually reproduce data magnetically, while discs reproduce data optically with lasers. Combinations of the above should also be included within the scope of computer-readable media.

Instructions may be executed by one or more processors, such as one or more digital signal processors (DSPs), general purpose microprocessors, application specific integrated circuits (ASICs), field programmable logic arrays (FPGAs), or other equivalent integrated or discrete logic circuitry. Accordingly, the term “processor,” as used herein may refer to any of the foregoing structure or any other structure suitable for implementation of the techniques described herein. In addition, in some aspects, the functionality described herein may be provided within dedicated hardware and/or software modules. Also, the techniques could be fully implemented in one or more circuits or logic elements.

The techniques of this disclosure may be implemented in a wide variety of devices or apparatuses, including a wireless handset, an integrated circuit (IC) or a set of ICs (e.g., a chip set). Various components, modules, or units are described in this disclosure to emphasize functional aspects of devices configured to perform the disclosed techniques, but do not necessarily require realization by different hardware units. Rather, as described above, various units may be combined in a hardware unit or provided by a collection of inter-operative hardware units, including one or more processors as described above, in conjunction with suitable software and/or firmware.

The foregoing disclosure includes various examples set forth merely as illustration. The disclosed examples are not intended to be limiting. Modifications incorporating the spirit and substance of the described examples may occur to persons skilled in the art. These and other examples are within the scope of this disclosure and the following claims.

What is claimed is:

1. A device comprising:
at least one processor configured to:
determine, based on a value of a voltage and a value of a current at a location of an electrical power system, a plurality of voltage features and a plurality of current features corresponding to the location;
determine, based on the plurality of voltage features and the plurality of current features, using a classification model, whether a fault has occurred in the electrical power system; and
responsive to determining that a fault has occurred, causing a protective device in the electrical power system to trip.

2. The device of claim 1, wherein:
determining the plurality of voltage features comprises:
determining, based on a first value of the voltage corresponding to a first phase at the location, a second value of the voltage corresponding to a second phase at the location, and a third value of the voltage corresponding to a third phase at the location, a positive sequence voltage corresponding to the location, a negative sequence voltage corresponding to the location, and a zero sequence voltage corresponding to the location; and
determining, for each of the first phase, the second phase, and the third phase, a respective total harmonic distortion of the respective voltage; and
determining the plurality of current features comprises:
determining, based on a first value of the current corresponding to the first phase, a second value of the current corresponding to the second phase, and a third value of the current corresponding to the third phase, a positive sequence current corresponding to the location, a negative sequence current corresponding to the location, and a zero sequence current corresponding to the location; and
determining, for each of the first phase, the second phase, and the third phase, a respective total harmonic distortion of the respective current.

3. The device of claim 2, wherein:
the plurality of voltage features further comprises the first value of the voltage, the second value of the voltage, and the third value of the voltage; and
the plurality of current features further comprises the first value of the current, the second value of the current, and the third value of the current.

4. The device of claim 1, wherein the classification model comprises a support vector machine (SVM)-based classification model.

5. The device of claim 1, wherein the at least one processor is further configured to:
responsive to determining that a fault has occurred, determine, based on power measurements at the location, an estimate of a time at which the fault occurred.

6. The device of claim 5, wherein determining the estimate of the time at which the fault occurred comprises:
determining, as the estimate of the time, a time at which at least one of (i) a rate of change of an active power at the location or (ii) a rate of change of a reactive power at the location exceeded a threshold rate of change.

7. The device of claim 1, wherein the device comprises a protective relay and causing the protective device to trip comprises tripping a circuit breaker of the protective relay.

8. A device comprising:
at least one processor configured to:
determine, based on a value of a voltage and a value of a current at a first location of an electrical power system, using a classification model, a respective indication, corresponding to the first location, of whether a fault is upstream or downstream from the first location;
determine, based on the respective indication corresponding to the first location and a respective indication corresponding to a neighboring location, whether the fault is in a neighborhood of the first location; and
responsive to determining that the fault is in a neighborhood of the first location, causing a protective device in the electrical power system that is in the neighborhood to trip.

9. The device of claim 8, further comprising outputting the respective indication corresponding to the first location.

10. The device of claim 9, wherein outputting the respective indication comprises:
responsive to determining the respective indication corresponding to the first location, waiting a defined period of time; and
outputting the respective indication corresponding to the first location after waiting the defined period of time.

11. The device of claim 8, wherein:
the value of the voltage comprises a first value of the voltage corresponding to a first phase at the location;
the value of the current comprises a first value of the current corresponding to the first phase; and
determining the respective indication corresponding to the first location is further based on a second value of the voltage corresponding to a second phase at the location, a second value of the current corresponding to the second phase, a third value of the voltage corresponding to a third phase at the location, and a third value of the current corresponding to the third phase.

12. The device of claim 11, wherein:
determining the respective indication corresponding to the first location further comprises determining, based on the first value of the voltage, the second value of the voltage, and the third value of the voltage, a positive sequence voltage corresponding to the location, a negative sequence voltage corresponding to the location, and a zero sequence voltage corresponding to the location; and
determining the respective indication corresponding to the first location is further based on the positive sequence voltage, the negative sequence voltage, and the zero sequence voltage.

13. The device of claim 8, wherein the classification model comprises a support vector machine (SVM)-based classification model.

14. The device of claim 8, wherein the device comprises a protective relay and causing the protective device to trip comprises tripping a circuit breaker of the protective relay.

15. A device comprising:
at least one processor configured to:
determine, based on a value of a voltage and a value of a current at a first location of an electrical power system, using a classification model, a respective indication, corresponding to the first location, of whether a fault is upstream or downstream from the first location;
determine, based on the respective indication corresponding to the first location and a respective indication corresponding to a neighboring location, the neighboring location being within a decision zone that includes the first location whether the fault is the decision zone; and
responsive to determining that the fault is in the decision zone, causing a protective device in the electrical power system that is in the decision zone to trip.

16. The device of claim 15, wherein the at least one processor is further configured to:
responsive to determining that the fault is not in the decision zone, output an indication of such determination.

17. The device of claim 15, wherein the classification model comprises a support vector machine (SVM)-based classification model.

18. The device of claim 15, wherein the device comprises a protective relay and causing the protective device to trip comprises tripping a circuit breaker of the protective relay.
